(19) United States
(12) Patent Application Publication
(10) Pub. No.: US 2026/0100707 A1
(43) Pub. Date: Apr. 9, 2026

(54) Level-Shifting Circuitry Devices and Methods

(71) Applicant: Arm Limited, Cambridge (GB)

(72) Inventors: Andy Wangkun Chen, Austin, TX (US); Mohit Chanana, Noida (IN); Rajesh ., Delhi (IN); Parveen Kumar, Ghaziabad (IN); Yew Keong Chong, Austin, TX (US)

(21) Appl. No.: 18/905,956

(22) Filed: Oct. 3, 2024

(51) Int. Cl. H03K 19/0185; G11C 8/06; G11C 8/08; G11C 8/18; H03K 5/135; H03K 19/20

(52) U.S. Cl. CPC H03K 19/018507; G11C 8/06; G11C 8/08; G11C 8/18; H03K 5/135; H03K 19/20

(57) ABSTRACT

A circuit for level-shifting includes a pulse-shaper circuit comprising a first PMOS transistor; and a level-shifting circuit, where the first PMOS transistor is configured to precharge a node on a wordline generation path of the level-shifting circuit. Also, a method of level-shifting includes detecting, at a PMOS transistor of a pulse-shaping circuit, a falling edge of a clock signal; and generating, by the pulse-shaping circuit, a pulse to activate the PMOS transistor to precharge a node on a wordline generation path of a level-shifting circuit. Another circuit for level-shifting includes a first PMOS transistor; and a level-shifting circuitry, where the circuit is configured to generate a pulse on a second voltage domain from a clock signal on a first voltage domain.

### FIELD

The present disclosure is generally related to level-shifting circuit devices and methods.

### DESCRIPTION OF RELATED ART

A large range level shifter (LRLS) is a circuit or device that can effectively translate signals between widely different voltage levels. This capability is crucial in systems where components operate at significantly varying power supplies, for example, such as in power electronics, automotive systems, and high-voltage measurement systems. In power electronics, LRLS circuitry may be used to interface between high-voltage power stages with low-voltage control circuitry. In automotive systems, LRLS circuitry may be used for handling signals from various voltage domains (e.g., 12V, 5V, 3.3V, etc.). Also, in high-voltage measurement systems, LRLS circuitry may be used to acquire data from high-voltage sources.

For digital circuits, the level-shifting contention problem occurs when interfacing between different voltage domains. For example, such a problem arises when two sides of an interface simultaneously attempt to drive a signal, leading to conflicts between the different voltage levels. This problem can result in: excessive power consumption, signal integrity issues, damage to input/output buffers, and unreliable data transmission (e.g., slower signal propagation due to contention between two separate networks).

In current wordline driver circuitry designs, LRLS circuitry generally require “weak”/“very slow” (as defined herein) PMOS transistors to “qualify” (e.g., overcome, compensate for, and/or mitigate) the contention problem. This is the case for both contention mitigation level shifters (CMLS) and NAND/NOR-gate-based level shifters. However, due to utilization of such weak PMOS transistors, for example, a comparatively “large” driver circuitry would cause an extensive fanout on a particular previous voltage stage transition of the LRLS.

In addition, to highlight drawbacks of various contention problem mitigation efforts, the upsizing of PMOS transistors would cause level-shifting capacity to be reduced; “too much” upsizing of NMOS transistors would inevitably “slow down” previous stage shifts, and thus, cause a power, performance, and area (PPA) penalty, while upsizing both NMOS and PMOS transistors would lead too great of a circuit size increase as well as have too large of an input capacitance. Hence, there is a need in the art for level range level shifter circuitry that can both maintain level-shifting capability and avoid timing penalties, yet operate and be implemented with PMOS transistors suitably sized to overcome the contention problem.

### BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1A is a schematic diagram of a portion of an example circuit in accordance with various implementations described herein.

FIG. 1B is an example waveform diagram in accordance with various implementations described herein.

FIG. 2 is a schematic diagram of an example portion of FIG. 1 in accordance with various implementations described herein.

FIG. 3 is a schematic diagram of an example portion of FIG. 1 in accordance with various implementations described herein.

FIG. 4 is an operational method in accordance with various implementations described herein.

FIG. 5 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

Implementations of the present disclosure are described below with reference to the drawings. In the description, common features are designated by common reference numbers throughout the drawings.

In one implementation, the present disclosure describes a circuit for level-shifting, which may include: a pulse-shaper circuit that includes a first PMOS transistor and a level-shifting circuit, which may be a NAND gate. The first PMOS transistor may be configured to precharge a node on a wordline generation path, such as for example, the reset path of the level-shifting circuit. In one example, the pulse-shaper circuit may correspond to pre-charge circuitry and/or pulse generation circuitry. Also, the first PMOS transistor may control and/or drive voltage, reset, and/or provide faster precharge at such a node on the wordline generation path. Hence, for instance, the first PMOS transistor may provide a reliable digital low value to “fix” a reset edge of a signal at the node. In certain examples, “precharging” the node refers to setting the node to a predetermined voltage level prior to an actual operation or evaluation phase of the circuit.

In another implementation, the disclosure describes a method of level-shifting, which includes: 1) detecting, at a PMOS transistor of a pulse-shaping circuit, a falling edge of a clock signal; and 2) generating, by the pulse-shaping circuit, a pulse at an end of a clock cycle to activate the PMOS transistor to set a node on a wordline generation path of a level-shifting circuit to a predetermined voltage level before an actual operation or evaluation phase of the circuit. In one example, the method of level-shifting may be used to qualify LRLS specifically when driving a large fanout. Sensing may be used as an alternative to the term detecting. The clock signal that is being detected may be a controlling gtp clock signal. The pulse being generated may be a falling edge of gtp_ce, output signal. In one aspect, the precharge to the node may provide a reliable digital low value.

In yet another implementation, the disclosure describes a pulse-shaping circuit for level-shifting, which includes: a first PMOS transistor; and a level-shifting circuitry, where: the circuit is configured to generate a pulse on a second voltage domain from a clock signal on a first voltage domain. In one example, the generated pulse may be a brief voltage transition signal.

Certain definitions have been provided herein for reference. The term VDDP is a first voltage supply (i.e., a first voltage domain) that is used for main power supply to power the core components of an integrated circuit. The term VDDCE is a second voltage supply (i.e., a second voltage domain; core voltage supply) specifically used to power critical core components of processor or other digital integrated circuitry. VDDP and VDDCE can have different voltage levels to optimize for power consumption and performance. For instance, core components may require a lower voltage for efficiency and to reduce heat generation.

In addition, voltage threshold (VT) refers to a minimum gate-source voltage required to create a conducting path in (e.g., “to turn on”) a MOSFET. For instance, common VT-types include: ULVT (Ultra Low Voltage Threshold): transistors with an extremely low VT (e.g., typically used in low-power applications where energy efficiency is the primary concern); LVT (Low Voltage Threshold): transistors with a lower VT compared to standard devices (e.g., often used in battery-powered devices and portable electronics); EVT (Enhanced or Extended Voltage Threshold): transistors with a higher VT compared to standard devices (e.g., generally used in high-performance applications where speed is prioritized). Thus, in order: EVT has a higher voltage threshold in comparison to LVT, which has a higher voltage threshold in comparison to ULVT. Accordingly, such VT-types can be used to categorize different VT-levels of transistors allowing circuit designers to optimize the trade-off between performance and power consumption in different parts of a circuit.

Also, in the current context, the terms “weak” and “strong” refers to transistor strength, e.g., a transistors width-to-length (W/L) ratio (i.e., sizing, size dimension). For instance, in comparison to strong transistors, weak transistors would have: a smaller W/L ratio, lower current drive capability, slower switching speed, decreased power consumption, smaller chip area, and higher on-resistance. Similarly, the terms “upsizing” and “bigger” refer to increasing the W/L ratio (i.e., sizing, size dimension) of transistors, while the terms “downsizing” and “smaller” refer to decreasing the W/L ratio. For instance, in comparison to downsized transistors, upsized transistors include: a higher current drive capability, faster switching speed, lower on-resistance, and increased power consumption and area.

Specifically, in one example scenario of level-shifting, certain input signals (e.g., xrow signals) may be on a first voltage domain (e.g., vddp voltage supply), while the level-shifting circuitry, itself, may be on a second voltage domain (e.g., vddce voltage supply). The contention problem would now occur when a “split is high” (e.g., when the vddce voltage supply is greater than the vddp voltage supply) and the voltage input of the PMOS transistors are, hence, partially activated. During such situations, to qualify for LRLS, it is essential that the NMOS transistors (e.g., NMOS transistor stack(s)) “win” (e.g., have dominant signal strength and influence within the level shifter circuit itself) over the partially “turned on” (i.e., partially activated, “poorly driven”) PMOS transistors. Hence, circuit designers would attempt to change the skew between PMOS and NMOS sizing. Nevertheless, by doing so, the requisite “weakness” of the PMOS transistors may not be fulfilled, and thus, a significant signal integrity and logic level issue occurs where the reset edge of the circuit does not provide a consistent and unambiguously recognized logic low (e.g., digital “0” value) state by the connected devices under all operating conditions, and specifically, at a node between PMOS and NMOS transistors that is on a wordline generation path or wordline driver circuitry.

Inventive aspects, as described herein, ensure that a reliable and complete logic low state is provided in LRLS circuitry. By doing so, such inventive aspects of the present invention provide the capability to control precharge of a wordline generation path, both in completeness and with precision, through such LRLS circuitry. Advantageously, these aspects allow for correct operation of the critical path in such digital circuitry, ensuring overall robustness and dependability of such digital systems. In various example implementations, inventive schemes and techniques envision a separate PMOS transistor outside of the LRLS circuitry that can be used to precharge a node of the LS circuitry. In addition, such schemes and techniques further envision the generation of a self-resetting precharge pulse to control precharge of a such a node upon detection of a falling edge of a controlling clock signal. Advantageously, such a self-resetting precharge pulse may be shared for all row clock signals (rclk). For instance, in certain cases, the separate PMOS transistors may repeat for each row clock signal, where each row clock signal may be used to control the selection and activation of different rows in a memory array. Moreover, such schemes and techniques provide the capability to utilize such a pulse on a separate and distinct voltage domain from an input control clock (e.g., gtp control signal). In doing so, the load on the input control clock would be reduced in comparison to non-level-shifting designs.

In addition, accordingly to various implementations, inventive aspects provide for PMOS transistors (e.g., PMOS transistors 121, 123) of LRLS circuitry that remain active after a reset of the pulse to be sized “extremely small” because the majority of the precharging aspect would be performed by a separate “big” PMOS (e.g., PMOS transistors 112) that would be “turned off” (deactivated). Hence, by allowing for the PMOS transistors of the LRLS circuitry to be made smaller, the response time of the LRLS circuitry may be improved, and thus allows for a faster falling transition of a wordline clock signal (e.g., nrow clock signal) resulting in a performance improvement of memory access time.

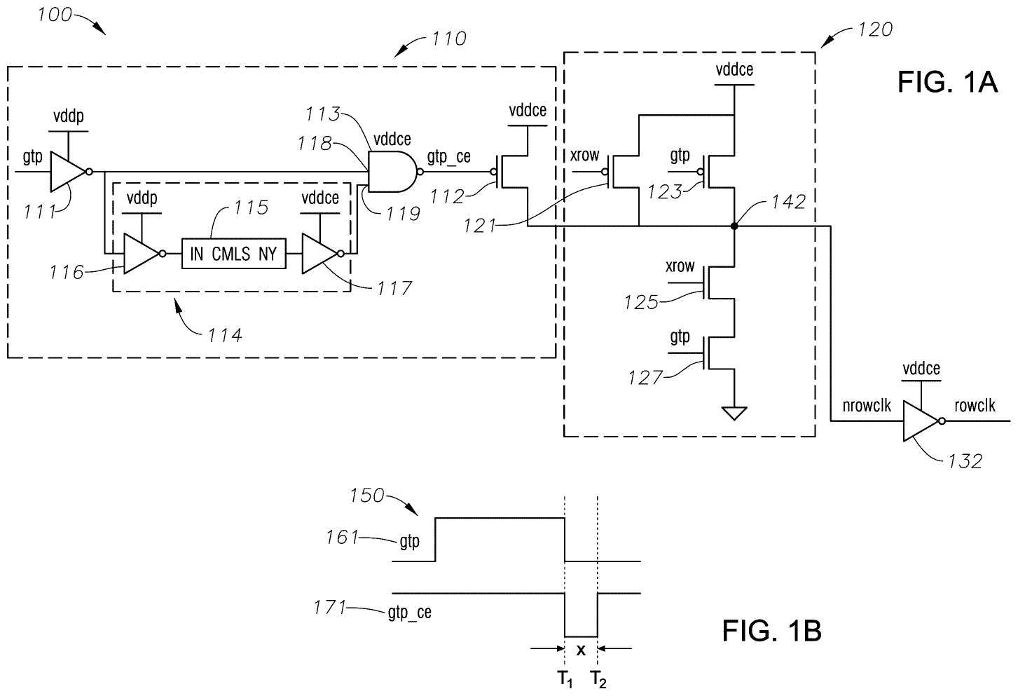

FIGS. 1A-1B depict one example circuit (FIG. 1A) to achieve an inventive pulse waveform (FIG. 1B). Referring to FIG. 1A, an example circuit 100 applicable for level-shifting in wordline driver circuitry is shown. As illustrated, the circuit 100 may include a pulse-shaper circuitry (i.e., pre-charge circuitry, pulse generation circuitry) 110 and a level-shifting circuit (e.g., a NAND gate) 120. In various implementations, the pulse-shaper circuitry 110 may include a first PMOS transistor 112 that is configured to precharge a node 142 on a wordline generation path (i.e., a reset path; nrowclk) of (and/or through) the level-shifting circuit 120. In doing so, the first PMOS transistor 112 is configured to control (e.g., “drive voltage at”, reset, and/or at least provide a “faster”) precharge of the voltage at the node 142. For instance, as discussed in the following paragraphs, the first PMOS transistor 112 is configured to provide a reliable logic low state (e.g., a digital “0” value), and hence, “fix” a reset edge of a voltage signal at the node 142. In certain implementations, the first PMOS transistor 112 may be sized 60 nm×3 nm, having a W/L ratio of 20 with ELVT voltage threshold. Additionally, in various implementations, separate first PMOS transistors 112 may repeat for each row clock signal (rowclk), where each row clock signal may be used to control the selection and activation of different rows in a memory array.

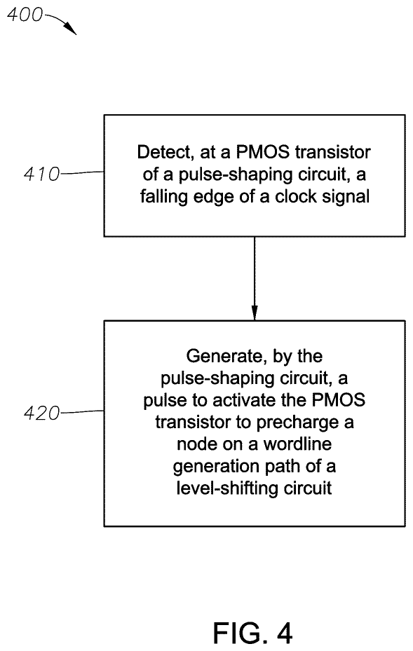

Referring to FIG. 1B, an example plot 150 of one cycle of a control clock signal (i.e., gtp signal 161) and a resultant pulse signal (i.e., gtp_ce 171) is shown. As may be appreciated, while FIG. 1A depicts one example circuit 100, any circuitry that provides a pulse-based signal (i.e., gte_ce 171) to precharge a node of large scale level-shifting (LRLS) circuitry (e.g., level-shifting circuitry 120) is envisioned to by utilized in conjunction with inventive methodologies as described herein. As illustrated, the nrowelk signal is configured to be precharged within the gtp_ce pulse signal 171 pulse width (i.e., the duration between the falling edge (at time T1) and the rising edge (at time T2) of gtp_ce pulse signal 171. Further description on generating such a pulse signal (i.e., at the falling edge of gtp_ce) is described with reference to the operation in FIG. 4 in the paragraphs below.

With reference to FIG. 1A, the pulse-shaper circuit 110 may also include first and second level-shifters. In various implementations, unlike the first PMOS transistor 112, the first and second level-shifters may be shared for a row clock signals (rowclk). In certain cases, the first level-shifter can be configured as a NAND gate 113, and the second-level shifter can be configured by one or more reset delays 114. In such cases, the one or more reset delays 114 may include a contention-mitigation level-shifter (CMLS) 115 and first and second inverters 116, 117. As illustrated, the NAND gate 113 may be configured to receive a clock signal (e.g., an inverted gtp signal) on a first input 118 of the NAND gate 113, where the clock signal is configured with a first operating voltage (e.g., vddp). In addition, the NAND gate 113 may be configured to receive a delayed version of the clock signal on a second input 119 of the NAND gate 113, where the delayed version of the clock signal is configured with a second operating voltage (i.e., vddce). As may be appreciated, the NAND gate 113 is designed to be as “strong” as possible so as to qualify the level-shifting circuit 120 and mitigate timing penalties, and aid in providing an optimal timing critical path (along with having “strong” NMOS transistors in the level-shifting circuit 120 as described below). In addition, the one or more reset delays 114 are thoughtfully placed, such that a “weak” PMOS transistor path (i.e., the path through the one or more reset delays 114) may aid in increasing the pulse of the delayed version of the clock signal. In doing so, the pulse shaper circuit 110 ensures that the gpt_ce pulse signal 171 is “strong enough” to charge the node 142 completely, and only then would the gpt_ce pulse signal 191 be set in an inactive state. Hence, to do so, by incorporating the extra delay that is provided by the one or more reset delays 114 (e.g., smaller PMOS transistors of the reset delays 114), the gpt_ce pulse signal 171 would have a pulse width that is “wide enough” to provide a longer reset window. In addition, one advantage of having two level-shifters in the pulse-shaper circuitry 110 is penalty of the reset edge of the node 142 may be effectively mitigated. For instance, while the level-shifting circuit 120 will have settling time of its own, the critical edge (i.e., the gtp_ce fall at time T1) would occur in just two stages, and afterwards, bigger PMOS transistors (in comparison) to those in the reset delays 114) can then also be utilized. In certain instances, as shown, the pulse-shaper circuit 110 may also include an inverter 111 to receive the initial clock signal (i.e., gtp clock signal).

In example implementations, the level-shifting circuit 120 may be arranged as a NAND gate, including: first and second PMOS transistors 121, 123 coupled in parallel, and first and second NMOS transistors 125, 127 coupled in series (e.g., arranged as an “NMOS stack”). As shown, the first PMOS transistor 121 and the first NMOS transistor 125 can be configured to receive an xrow clock signal, while the second PMOS transistor 123 and the second NMOS transistor 127 are configured to receive a gtp clock signal 127. As may be appreciated, the node 142 is coupled between (respective source ends of) the PMOS transistors 121, 123 and the NMOS transistor 125, 127 of the NMOS stack. In certain examples, the first and second NMOS transistors may each be sized as 32 nm×2 nm with ELVT voltage threshold. In certain examples, the first and second PMOS transistors 121, 123 may be designed with the same or bigger VT as the first PMOS transistor 112. In such examples, however, the first PMOS transistor 112 would invariably be sized larger than the first and second PMOS transistors 121, 123.

In one example operation of the inventive design, with reference to FIGS. 1A-1B, the level-shifting circuitry 120 would be designed to be skewed in such a way to qualify a large split (e.g., PMOS transistors 121, 123 are weakly-sized). In addition, the pulse-shaper circuit 110 (including PMOS transistor 112 sized “bigger” than PMOS transistors 121, 123) is designed to be controlled through a pulse signal (e.g., gtp_ce 171). For instance, when the gtp clock signal “falls”, the inverted gtp clock signal goes “high” (e.g., to a digital “1” value). Thus, both inputs signals at NAND gate 113 are “high” (e.g., digital “1” values), and correspondingly, the NAND gate 113 would go from a digital “1” value to a digital “0” value. Hence, by doing so, the pulse signal gtp_ce 171 would “fall” (at the end of the clock cycle) and transition from a digital “1” value to a digital “0” value at time T1. In such a manner, by detecting the falling edge of gtp clock signal 161, the gtp_ce pulse signal 171 ensures that PMOS transistor 112 precharges the node 142. Next, upon such precharge completion, the PMOS transistor 112 is disabled. Thus, in a next cycle, when the gtp clock signal 161 goes “high”, only the two weak PMOS transistors 121, 123 would be activated, and, advantageously, such activations can be easily overcome by the stronger NMOS transistors 125, 127.

Accordingly, by such a parallel PMOS transistor circuit design, the level-shifting circuit 120 may be pulse-based precharged, and so, when it is desired that PMOS transistors 121, 123 be active and precharge the node 142 to, for example, drive a large fanout (e.g., LRLS level-shifting at 400 mv), it can properly do so. For instance, because the pulse-shaper circuit 110 is pulse-based, the PMOS 112 would be disabled toward the end of the clock cycle, and thus, the weaker PMOS transistors 121, 123 would maintain the precharge of node 142 (i.e., hold the node 142 to a digital “1” value). Correspondingly, at this juncture, the node 142 is configured to receive and allow propagation of a clock signal (i.e., nrowclk) to a plurality (e.g., a large quantity) of logic gates (not shown) (i.e., drive a large fanout). For instance, an inverter 132 (as representing a “big” driver) may receive the clock signal (i.e., nrowelk) and transmit an output signal (rowclk) to the plurality of logic gates (not shown). Also, advantageously, such PMOS transistors 121, 123 can be configured to have (significantly) decreased size dimensions (e.g., “a very small size”) or lower voltage-threshold (VT)-types in comparison to the NMOS transistors 125, 127. Such PMOS transistors 121, 123 (e.g., having the smaller size or lower VT-type) can be configured to increase the speed of the nrow clock signal transition, and thus, assist in memory access time. In addition, by designing such PMOS transistors 121, 123 in such a manner, the response time of the NAND gate (i.e., the level-shifting circuitry 120) may be improved due to improved “loading” on the internal clk signal as well as the NAND gate (i.e., the level-shifting circuitry 120) trip point, thus, realizing a performance improvement over conventional circuitry.

Advantageously, by allowing a faster falling transition of the nrow clock signal (nrowclk), the PMOS transistors 121, 123 would be better controlled by the level-shifting circuit 120. Thus, a timing improvement may be achieved in terms of the critical edge of the signal. As may be appreciated, the NAND gate design of the level-shifting circuitry 120 is merely one example implementation. In alternative implementations, according to inventive schemes and techniques, other types of level-shifting circuitry having weaker PMOS transistors may be implemented.

In various implementations, the first PMOS transistor 112 of the pulse-shaper circuit 110 is coupled in parallel to the PMOS transistors 121, 123 of the level-shifting circuit 120. In addition, in certain example designs, the first PMOS transistor 112 of the pulse-shaper circuit 110 includes an increase size-dimension (as defined herein) in comparison to the PMOS transistors 121, 123 of the level-shifting circuit 120. In such examples, however, the first and second PMOS transistors 121, 123 may be designed with the same or higher voltage threshold (VT) level in comparison to the first PMOS transistor 112. In alternative example designs, the first PMOS transistor 112 of the pulse-shaper circuit 110 may be configured with a higher VT-type (as defined herein) in comparison to the PMOS transistors 121, 123 of the level-shifting circuit 120. Advantageously, such inventive designs allow for the PMOS transistor 112 to be “stronger” than the PMOS transistors 121, 123, and thus, aid in providing a “faster” precharge of the node 142.

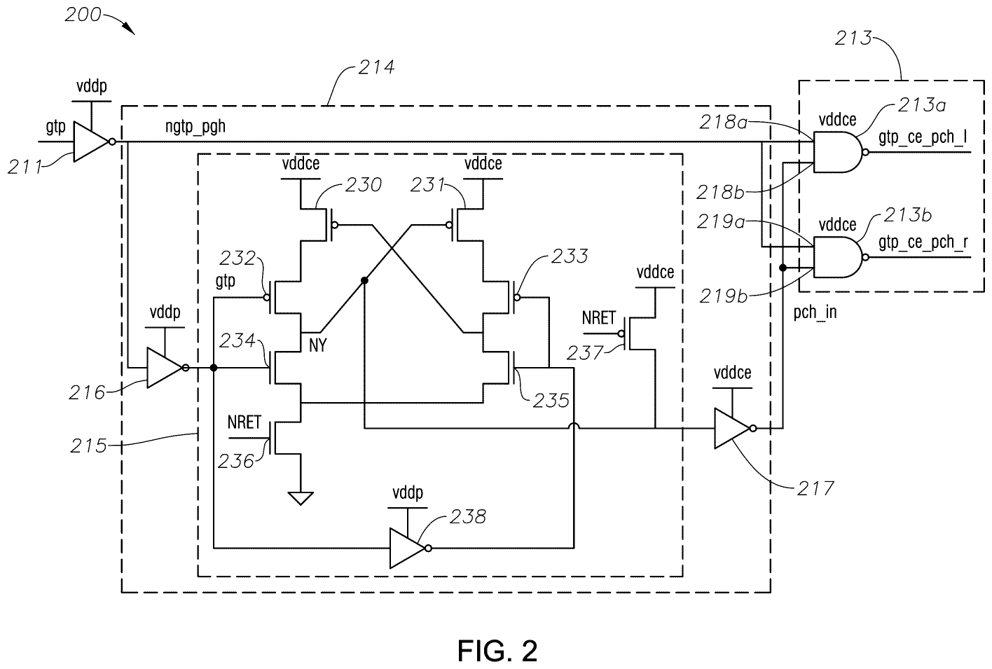

Referring to FIG. 2, example circuit 200 corresponding to a detailed implementation of a portion of the pulse-shaper circuit 110 of FIG. 1 is shown. In certain implementations, the circuit 200 includes first and second level-shifters. As illustrated, the first level-shifter can be configured as parallel NAND gates 213a, 213b (i.e., first and second NAND gates), and the second-level shifter can be configured by one or more reset delays 214.

In some implementations, the first NAND gate 213a may be configured to receive a clock signal (i.e., an inverted gtp signal) on a first input 218a of the first NAND gate 213a, where the clock signal is configured with a first operating voltage (i.e., vddp, first voltage domain). In addition, the first NAND gate 213a may be configured to receive a delayed version of the clock signal on a second input 219a of the first NAND gate 213a, where the delayed version of the clock signal is configured with a second operating voltage (i.e., vddce, second voltage domain). Similarly, the second NAND gate 213b may be configured to receive a clock signal (e.g., an inverted gtp signal) on a first input 219a of the second NAND gate 213b, where the clock signal is configured with the first operating voltage (i.e., vddp, first voltage domain). In addition, the second NAND gate 213b may be configured to receive a delayed version of the clock signal on a second input 219b of the second NAND gate 213b, where the delayed version of the clock signal is configured with the second operating voltage (i.e., vddce, second voltage domain).

In certain cases, each of the parallel NAND gates 213a, 213b may be configured with PMOS transistors with unequal size dimensions (as defined herein). For instance, smaller-sized PMOS transistors may receive the clock signal (e.g., an inverted gtp signal) configured with the first operating voltage, vddp (i.e., first voltage domain), while larger-sized PMOS transistors may receive the delayed version of the clock signal configured with the second operating voltage, vddce (i.e., a second voltage domain).

In some implementations, the one or more reset delays 214 may include a contention-mitigation level-shifter (CMLS) 215 and first and second inverters 116, 117. As illustrated, as an example, the CMLS 215 may include PMOS transistors 230, 231, 232, 233, and 237, and NMOS transistors 234, 235, and 236. For instance, in certain cases, each of PMOS transistors 230, 231 may be designed with a 32 nm width, ULVT; each of PMOS transistors 232, 233 may be designed with a 26 nm width, LVLT; each of NMOS transistors 234, 235 may be designed as 32 nm width×2 nm length, ULVT; and NMOS transistor 236 may be designed with a 32 nm width×4 nm length, ULVT.

In certain implementations, a PMOS transistor (e.g., PMOS transistor 232) of the CMLS 215 may be configured with a decreased size dimension (i.e., smaller size) or a lower VT-type in comparison to the first PMOS transistor 112. In such cases, such a PMOS transistor (e.g., PMOS transistor 232) of the CMLS 215 can be configured to boost (i.e., strengthen) the delayed version of the clock signal. Correspondingly, such a boosted delayed version of the clock signal is configured to boost an output pulse signal (e.g., gtp_ce, gtp_ce_pch_1, gtp_ce_pch_r) of the pulse-shaper circuit 110. Moreover, a signal delay associated with such a PMOS transistor (e.g., PMOS transistor 232) of CMLS 215 can be configured to increase a reset window of the output pulse signal (i.e. pulse gtp_ce) of the pulse-shaper circuit. Accordingly, the second level shifter is, thus, configured such that the “weak” PMOS path (e.g., through inverter 217) would assist in increasing the pulse of the delayed version of the clock signal (e.g., the signal output from inverter 217). Advantageously, by doing so, the gtp_ce output signal pulse would hence be “strong enough” to charge the node 142 completely, and only upon such a completion would the pulse-shaper circuit be deactivated (e.g., the PMOS 112 be deactivated, resulting in a rising edge of the gtp_ce signal at time T2 as shown in FIG. 1B).

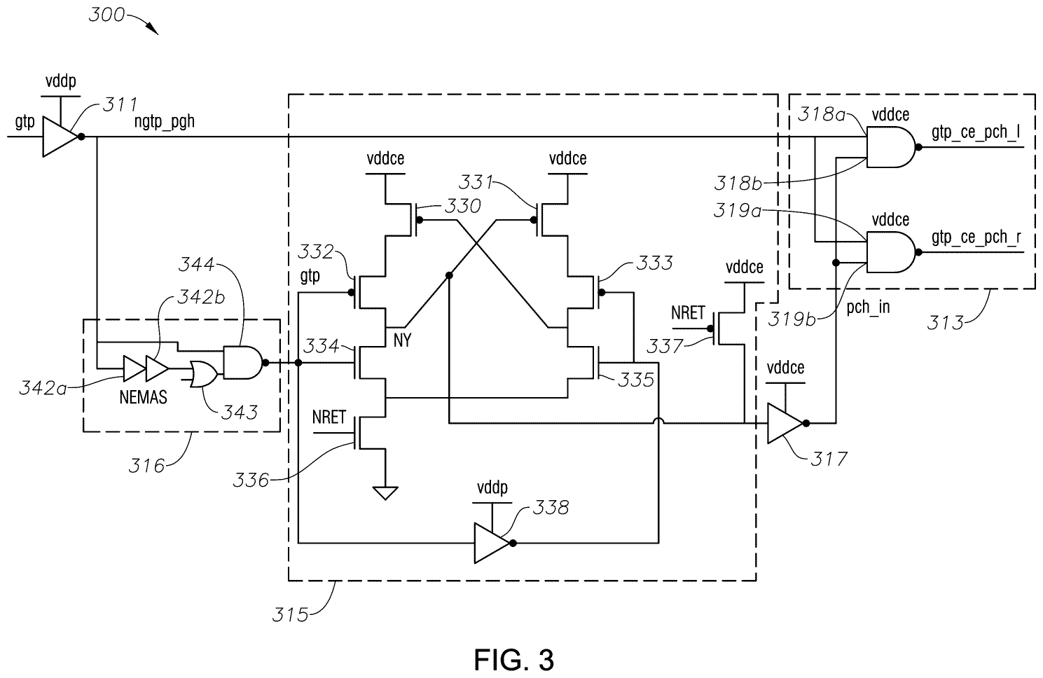

Referring to FIG. 3, example circuit 300 corresponding to a detailed implementation of a portion of the pulse-shaper circuit 110 of FIG. 1 is shown. As illustrated, the example circuit 300 may be substantially the same as example circuit 200, with the exception that a first inverter 216 in FIG. 2 has now been replaced by delay control circuitry 316 (i.e., delay control stage, Electrostatic Discharge Merger Avoidance Scheme (EMAS) control circuitry). In FIG. 3, the same or similar circuit elements denoted as 200s reference numerals, are herein denoted as 300s reference numerals. The description of such circuit elements have not been repeated but are the same as in FIG. 2.

In certain implementations, the delay control circuitry 316 includes: first and second buffers 342a, 342b; an OR gate 343; and a NAND gate 344. In some instances, first and second buffers 342a, 242b are coupled in series to a first input of the OR gate 343; a delay control input signal (i.e., pin, NEMAS input) is coupled to a second input of the OR gate 343; a clock signal (gtp) of the pulse-shaper circuitry 110 is coupled to a first input of the NAND gate 344; the output of the OR gate 343 is coupled to a second input of the NAND gate 344; and the output of the NAND gate 344 corresponds to a delayed control signal (e.g., gtp_ce pulse signal). As can be appreciated, by “mixing” with EMAS, one additional NAND gate (i.e., NAND gate 344) would be utilized. For instance, the NAND gate 344 can be configured to operate as a delay controlling stage. Hence, when an NEMAS input pin is set to a digital “1” value, then the two buffers 342a, 342b are bypassed. Correspondingly, when NEMAS set to a digital “0” value, instead of having the NAND gate 344 path selected, the EMAS control path would be provided from the reset of the gtp_ce signal 161. Thus, for example, when the gtp clock signal 161 falls, the reset edge that travels through the path would be delayed, which in turn, would increase the pulse signal 171 (gtp_ce) (width of pulse).

Advantageously, the delay control circuitry 316 provides the capability for designers to increase the pulse width (i.e., the duration X between time T1 and time T2 as shown in FIG. 1B) of the gtp_ce pulse for debugging purposes. Advantageously, such level-shifter debugging may be programmable such that if there are any issues on the silicon, the pulse width of the pulse signal 171 may be tweaked. For instance, the debugging may involve: voltage stress testing to identify threshold issues and breakdown points, transient response analysis using fast triggers, current distribution monitoring to identify uneven current flow, failure mode analysis to study robustness and reliability, and cross-domain interaction analysis.

Referring to FIG. 4, a flowchart of an example operational method 400 (i.e., procedure) is shown. Advantageously, in various implementations, the method 500 provides the capability to qualify a large-scale level-shifter circuitry (LRLS) specifically when driving a large fanout in wordline generation paths. The method 400 may be implemented with reference to circuit implementations as shown in FIGS. 1-3.

At block 410, the example method 400 includes: detecting (i.e., sensing), at a PMOS transistor of a pulse-shaping circuit, a falling edge of a (controlling) clock signal (gtp). For instance, as described with reference to FIGS. 1-3, at a PMOS transistor 112 of a pulse-shaping circuit 110, a falling edge (at time T1) of a (controlling) clock signal (i.e., gtp signal) may be detected (i.e., sensed).

At block 420, the example method 400 includes: generating, by the pulse-shaping circuit, a pulse (i.e., duration between a falling edge of gtp_ce output signal to a rising edge of gte_ce output signal at an end of a single clock cycle) to activate the PMOS transistor to (control a voltage) precharge (i.e., provide a reliable “0”) (of) a node on a wordline generation path of a level-shifting circuit. For instance, as described with reference to FIGS. 1-3, by the pulse-shaping circuit 110, a pulse (i.e., a duration (X) commencing at a falling edge of gtp_ce output signal (at time T1) to a rising edge of gte_ce output signal (at time T2) in a single clock cycle; a pulse-width) may be generated to activate the PMOS transistor 112 to (control a voltage) precharge (i.e., provide a reliable “0”) (of) a node 142 on a wordline generation path (e.g., the reset path; nrowclk) of (and/or through) the level-shifting circuit 120.

In certain implementations, the example method 400 further includes: in response to a completion of the (voltage) precharge of the node 142, disabling (i.e., de-activating) the PMOS transistor 112. For instance, as the method 400 is incorporated in a pulse-based circuit, e.g., pulse-based circuit 110, upon a short delay, the gte_ce pulse may automatically be reset to a “high” state again after a “short” delay (e.g., as shown by the duration X at time T2 in FIG. 1B).

In some cases, the example method 400 further includes: providing the clock signal (i.e., gtp clock signal) to a first input 118 of the NAND gate 113 coupled to PMOS transistor 112, and providing a delayed version of the clock signal to a second input 119 of the PMOS transistor 112, where the clock signal and the delayed version of the clock signal have different operating voltages (e.g., vddp for the clock signal, and vddce for the delayed version of the clock signal).

In certain instances, the example method 400 further includes: boosting (strengthening), by a second PMOS transistor (e.g., PMOS transistor 232, 332), the delayed version of the clock signal (i.e., output signal of second inverter 217) where the second PMOS transistor is configured with a decreased size dimension (i.e., smaller size) or a lower voltage-threshold (VT)-type in comparison to the first PMOS transistor 112, and the boosted delayed version of the clock signal is configured to strengthen the pulse (i.e., at the time T1 at the falling edge of gtp_ce 171 (e.g., provide a “stronger” digital “0” at the node 142). In some implementations, a delay control circuitry 316 of the pulse-shaping circuit 110 may provide a delay of the clock signal (gtp), where such a delay of the clock signal is configured to increase a pulse duration (i.e., pulse width of gtp_ce, reset window) of the pulse (gtp_ce). In some cases, the falling edge of the clock signal (gtp) (at time T1) may be detected if an output of a first level shifter (e.g., NAND gate 113, 213, 313) of the pulse-shaping circuit 110 transitions from a digital high (e.g., a digital “1”) to a digital low (e.g., a digital “0”). In certain instances, the clock signal (i.e., gtp) is configured with a first operating voltage (vddp), and the pulse (gtp_ce) is configured with a second operating voltage (vddce).

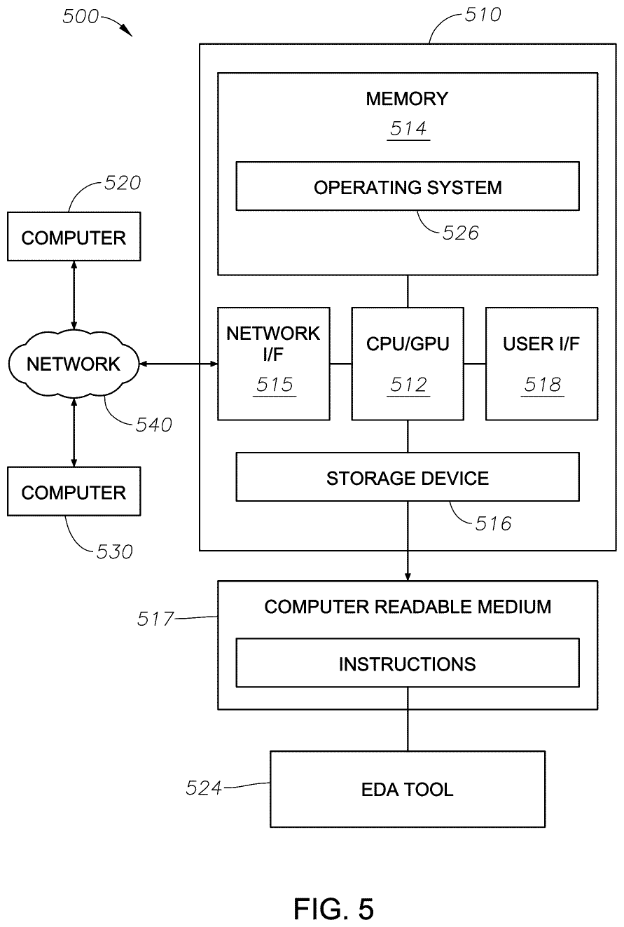

Also, according to other aspects of the operational methods, an output may be generated based on the operational dispositions. For example, with reference to various implementations as described in FIGS. 1-3, an output (i.e., a pulse-shaping circuit design, LRLS circuit design) (e.g., a memory architecture, multi-threshold offerings for memory compilers) may be generated. In some implementations, the circuit design tool 524 (as described with reference to FIG. 5) may allow users to input certain values, and generate circuit designs incorporating the inventive pulse-shaping/LRLS designs.

FIG. 5 illustrates example hardware components in the computer system 500 that may be used to determine an optimized wiring positioning and to generate an integrated circuit design/memory architecture output. In certain implementations, the example computer system 500 (e.g., networked computer system and/or server) may include circuit design tool 824 and execute software based on the procedure as described with reference to the method 400 in FIG. 4. In certain implementations, the circuit design tool 524 may be included as a feature of an existing memory compiler software program allowing users to input various criteria, including, but not limited to, sizing dimensions and/or VT levels.

The circuit design tool 524 may provide generated computer-aided physical layout designs for memory architecture. The procedure 400 may be stored as program code as instructions 517 in the computer readable medium of the storage device 516 (or alternatively, in memory 514) that may be executed by the computer 510, or networked computers 520, 530, other networked electronic devices (not shown) or a combination thereof. In certain implementations, each of the computers 510, 520, 530 may be any type of computer, computer system, or other programmable electronic device. Further, each of the computers 510, 520, 530 may be implemented using one or more networked computers, e.g., in a cluster or other distributed computing system.

In certain implementations, the system 500 may be used with semiconductor integrated circuit (IC) designs that contain all standard cells, all blocks or a mixture of standard cells and blocks. In a particular example implementation, the system 500 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 500 may be stored in one or more of memory 514 or storage devices 516 of computer 510 or in networked computers 520, 530.

In one implementation, the computer 500 includes a central processing unit (CPU) 512 having at least one hardware-based processor coupled to a memory 514. The memory 514 may represent random access memory (RAM) devices of main storage of the computer 510, supplemental levels of memory (e.g., cache memories, non-volatile or backup memories (e.g., programmable or flash memories)), read-only memories, or combinations thereof. In addition to the memory 514, the computer system 500 may include other memory located elsewhere in the computer 510, such as cache memory in the CPU 512, as well as any storage capacity used as a virtual memory (e.g., as stored on a storage device 516 or on another computer coupled to the computer 510).

The computer 510 may further be configured to communicate information externally. To interface with a user or operator (e.g., a circuit design engineer), the computer 510 may include a user interface (I/F) 518 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 510 may include a network interface (I/F) 515 which may be coupled to one or more networks 540 (e.g., a wireless network) to enable communication of information with other computers and electronic devices. The computer 560 may include analog and/or digital interfaces between the CPU 512 and each of the components 514, 515, 516, and 518. Further, other non-limiting hardware environments may be used within the context of example implementations.

The computer 510 may operate under the control of an operating system 526 and may execute or otherwise rely upon various computer software applications, components, programs, objects, modules, data structures, etc. (such as the programs associated with the procedure 400 and related software). The operating system 528 may be stored in the memory 514. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 526 in the example of FIG. 5 is shown in the memory 514, but components of the aforementioned software may also, or in addition, be stored at non-volatile memory (e.g., on storage device 516 (data storage) and/or the non-volatile memory (not shown). Moreover, various applications, components, programs, objects, modules, etc. may also execute on one or more processors in another computer coupled to the computer 510 via the network 540 (e.g., in a distributed or client-server computing environment) where the processing to implement the functions of a computer program may be allocated to multiple computers 520, 530 over the network 540. In example implementations, circuit diagrams have been provided in FIGS. 1-3, whose redundant description has not been duplicated in the related description of analogous circuit diagrams. It is expressly incorporated that the same diagrams with identical symbols and/or reference numerals are included in each of embodiments based on its corresponding figure(s).

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

1. A circuit for level-shifting comprising:
a pulse-shaper circuit comprising a first PMOS transistor; and
a level-shifting circuit, wherein: the first PMOS transistor is configured to precharge a node on a wordline generation path of the level-shifting circuit.

2. The circuit of claim 1, wherein:
the first PMOS transistor of the pulse-shaper circuit is coupled in parallel to PMOS transistors of the level-shifting circuit.

3. The circuit of claim 1, wherein:
the first PMOS transistor of the pulse-shaper circuit comprises an increased size dimension in comparison to the PMOS transistors of the level-shifting circuit.

4. The circuit of claim 1, wherein:
the first PMOS transistor of the pulse-shaper circuit is configured with a higher voltage-threshold (VT)-type in comparison to one or more PMOS transistors of the level-shifting circuit.

5. The circuit of claim 1, wherein the pulse-shaper circuit further comprises first and second level-shifters.

6. The circuit of claim 5, wherein:
the first level-shifter is configured by a NAND gate, and
the second level-shifter is configured by one or more reset delays, wherein the one or more reset delays comprise at least a contention-mitigation level shifter (CMLS).

7. The circuit of claim 6, wherein the NAND gate is configured to receive:
a clock signal on a first input of the NAND gate, wherein the clock signal is configured with a first operating voltage; and
a delayed version of the clock signal on a second input of the NAND gate, wherein the delayed version of the clock signal is configured with a second operating voltage.

8. The circuit of claim 6, wherein:
the CMLS comprises a second PMOS transistor, and
the second PMOS transistor of the CMLS is configured with a decreased size dimension or a lower voltage-threshold (VT)-type in comparison to the first PMOS transistor.

9. The circuit of claim 8, wherein:
the second PMOS transistor is configured to boost the delayed version of the clock signal, and
the boosted delayed version of the clock signal is configured to boost an output pulse signal of the pulse-shaper circuit, and
a signal delay associated with the second PMOS transistor is configured to increase a reset window of the output pulse signal of the pulse-shaper circuit.

10. The circuit of claim 1, wherein:
the level-shifting circuitry is arranged as a NAND gate;
the NAND gate comprises two PMOS transistors coupled in parallel and two NMOS transistors coupled in series; and
the node is coupled between the PMOS transistors and the NMOS transistors; and
the node is configured to transmit a clock signal to a plurality of logic gates.

11. The circuit of claim 10, wherein:
PMOS transistors of the level-shifting circuit are configured to maintain the precharge of the node;
the PMOS transistors of the level-shifting comprise a decreased size or a lower voltage-threshold (VT)-type in comparison to the NMOS transistors; and
the PMOS transistors are configured to increase the speed of transition of the clock signal.

12. The circuit of claim 1, further comprising:
delay control circuitry comprising:
two buffers;
an OR gate; and
a NAND gate, wherein:
the two buffers are coupled in series to a first input of the OR gate,
a delay control input coupled to a second input of the OR gate,
a clock signal of the pulse-shaper circuitry coupled to a first input of the NAND gate,
the output of the OR gate coupled to a second input of the NAND gate,
the output of the NAND gate corresponds to a delayed control signal.

13. A method of level-shifting comprising:
detecting, at a PMOS transistor of a pulse-shaping circuit, a falling edge of a clock signal; and
generating, by the pulse-shaping circuit, a pulse to activate the PMOS transistor to precharge a node on a wordline generation path of a level-shifting circuit.

14. The method of claim 13, further comprising:
in response to a completion of the precharge of the node, disabling the PMOS transistor.

15. The method of claim 13, further comprising:
providing the clock signal to a first input of a NAND gate coupled to the PMOS transistor;
providing a delayed version of the clock signal to a second input of the NAND gate coupled to the PMOS transistor, wherein: the clock signal and the delayed version of the clock signal have different operating voltages.

16. The method of claim 13, further comprising:
boosting, by a second PMOS transistor, the delayed version of the clock signal, wherein:
the second PMOS transistor is configured with a decreased size dimension or a lower voltage-threshold (VT)-type in comparison to the first PMOS transistor, and
the boosted delayed version of the clock signal is configured to strengthen the pulse.

17. The method of claim 13, further comprising:
providing, by a delay control circuitry of the pulse-shaping circuit, a delay of the clock signal, wherein the delay of the clock signal is configured to increase a pulse duration of the pulse.

18. The method of claim 13, wherein:
the falling edge of the clock signal is detected if an output of a first level shifter of the pulse-shaping circuit transitions from a digital high to a digital low, or wherein:
the clock signal is configured with a first operating voltage, and
the pulse is configured with a second operating voltage.

19. A circuit for level-shifting comprising:
a first PMOS transistor; and
a level-shifting circuitry, wherein:
the circuit is configured to generate a pulse on a second voltage domain from a clock signal on a first voltage domain.

20. The circuit of claim 19, wherein:
the level-shifting circuitry comprising: a NAND gate and one or more reset delays,
the NAND gate comprises a first level shifter and the one or more reset delays comprise a second level shifter,
the one or more reset delays comprise a second PMOS transistor, and
the second PMOS transistor comprises a decreased size in comparison to the first PMOS transistor.
